(19) United States
(12) Patent Application Publication
(10) Pub. No.: US 2025/0264893 A1
(43) Pub. Date: Aug. 21, 2025

(54) METHOD OF CONTROLLING BATTERY ASSEMBLY AND SYSTEM FOR BATTERY MANAGEMENT

(71) Applicant: Samsung SDI Co., Ltd., Yongin-si (KR)

(72) Inventors: Byounggul Oh, Yongin-si (KR); Youngshik Cho, Yongin-si (KR); Myeongju Park, Yongin-si (KR); Daejin Jeong, Yongin-si (KR); Youngbae Song, Yongin-si (KR)

(73) Assignee: Samsung SDI Co., Ltd., Yongin-si (KR)

(21) Appl. No.: 18/805,736

(22) Filed: Aug. 15, 2024

(30) Foreign Application Priority Data
Feb. 21, 2024 (KR) 10-2024-0025248

(51) Int. Cl. G05D 15/01; G01R 31/367; G06N 20/00; H01M 10/42

(52) U.S. Cl. CPC G05D 15/01; G01R 31/367; G06N 20/00; H01M 10/425; H01M 2010/4271; H01M 2220/20

(57) ABSTRACT

A method of controlling a battery assembly comprising, measuring a pressure applied to a battery assembly to obtain a measured pressure value, receiving battery operating data of the battery assembly, estimating a sensitivity of battery input and output based on the measured pressure value and the battery operating data and generating a pressure control command based on the sensitivity of battery input and output and the battery operating data, wherein the sensitivity of battery input and output represents a sensitivity of the battery assembly to the pressure applied to the battery assembly.

### CROSS-REFERENCE TO RELATED APPLICATIONS

This present application claims priority to and the benefit under 35 U.S.C. § 119(a)-(d) of Korean Patent Application No. 10-2024-0025248, filed on Feb. 21, 2024, in the Korean Intellectual Property Office, the entire disclosure of which is incorporated herein by reference.

### FIELD

Aspects of embodiments of the present disclosure relate to a method of controlling a battery assembly and a system for battery management.

### BACKGROUND

Secondary batteries are rechargeable batteries. Rechargeable batteries refer to batteries that may be charged and discharged a plurality of times. Such secondary batteries are mainly used in various applications such as electronics (e.g., smartphones, laptops, and tablets), electric vehicles, solar power generation, and emergency power supplies. In particular, lithium-ion batteries are used in a variety of electronics and electric vehicles due to high energy density and high charge and discharge efficiency thereof.

The above information disclosed in this Background section is for enhancement of understanding of the background of the present disclosure, and therefore, it may contain information that does not constitute related (or prior) art.

### SUMMARY

An objective of the present disclosure is to provide a method of controlling a battery assembly and a system for battery management in order to overcome the problems described herein.

These and other aspects and features of the present disclosure will be described in or will be apparent from the following description of embodiments of the present disclosure.

To solve the above technical problem, a method of controlling a battery assembly according to some embodiments of the present disclosure is provided comprising, measuring a pressure applied to a battery assembly to obtain a measured pressure value, receiving battery operating data of the battery assembly, estimating a sensitivity of battery input and output based on the measured pressure value and the battery operating data and generating a pressure control command based on the sensitivity of battery input and output and the battery operating data, wherein the sensitivity of battery input and output represents a sensitivity of the battery assembly to the pressure applied to the battery assembly.

According to some embodiments of the present disclosure, the battery operating data comprises data about at least one of a state of health (SOH), a state of charge (SOC), a current rate (C-rate), charge/discharge, a temperature, a voltage, an internal resistance, or a pressure associated with the battery assembly.

According to some embodiments of the present disclosure, the estimating of the sensitivity of battery input and output comprises estimating the sensitivity of battery input and output using a battery input/output identification model, wherein the battery input/output identification model is a model trained to identify an input-output sensitivity of the battery assembly.

According to some embodiments of the present disclosure, the battery input/output identification model is trained based on measured pressure data and estimated pressure data, wherein the measured pressure data comprises the measured pressure value obtained by measuring the pressure applied to the battery assembly, and the estimated pressure data comprises a pressure value estimated by the battery input/output identification model based on the battery operating data.

According to some embodiments of the present disclosure, the battery input/output identification model is a model trained using a gradient descent method.

According to some embodiments of the present disclosure, the generating of the pressure control command comprises generating the pressure control command using a controller model, wherein the controller model is a model trained to determine a pressing force value at which a degree of degradation of the battery assembly is minimized.

According to some embodiments of the present disclosure, the controller model is trained based on target force data and estimated force data, wherein the target force data comprises a pressing force value determined from a predetermined lookup table, and the estimated force data comprises a pressing force value estimated by the controller model based on the battery operating data and the sensitivity of battery input and output.

According to some embodiments of the present disclosure, the lookup table is a lookup table associated with the battery operating data and the degree of degradation of the battery assembly.

According to some embodiments of the present disclosure, the controller model is a model trained using a gradient descent method.

According to some embodiments of the present disclosure, the sensitivity of battery input and output is defined by the following equation: the sensitivity of battery input and output=∂y/∂u, where y is a pressure output of the battery assembly, and u is a force input applied to the battery assembly.

According to some embodiments of the present disclosure, the method further comprising controlling a pressure regulator to apply a pressure to the battery assembly, based on the pressure control command.

According to some embodiments of the present disclosure, the method further comprising, after the controlling of the pressure regulator, measuring a pressure applied to the battery assembly to obtain a changed pressure value.

To solve the above technical problem, a battery management system according to some embodiments of the present disclosure is provided comprising a battery assembly comprising a plurality of battery cells, a sensor part configured to measure a pressure applied to the battery assembly, a pressure regulator provided on the battery assembly and a controller configured to receive a measured pressure value from the sensor part and control the pressure regulator, wherein the controller comprises, a sensitivity estimator configured to estimate a sensitivity of battery input and output based on the measured pressure value and battery operating data and a control command generator configured to generate a pressure control command based on the sensitivity of battery input and output and the battery operating data.

According to some embodiments of the present disclosure, the battery operating data comprises data about at least one of a state of health (SOH), a state of charge (SOC), a charge rate (C-rate), charge/discharge, a temperature, a voltage, an internal resistance, or a pressure associated with the battery assembly.

According to some embodiments of the present disclosure, the sensitivity estimator estimates the sensitivity of battery input and output using a battery input/output identification model, wherein the battery input/output identification model is trained to identify an input-output sensitivity of the battery assembly.

According to some embodiments of the present disclosure, the battery input/output identification model is trained based on measured pressure data and estimated pressure data, wherein the measured pressure data comprises the measured pressure value obtained by measuring the pressure applied to the battery assembly, and the estimated pressure data comprises a pressure value estimated by the battery input/output identification model based on the battery operating data.

According to some embodiments of the present disclosure, the control command generator generates the pressure control command using a controller model, wherein the controller model is a model trained to minimize a degree of degradation of the battery assembly.

According to some embodiments of the present disclosure, the controller model is trained based on target force data and estimated force data, wherein the target force data comprises a pressing force value determined from a predetermined lookup table, and the estimated force data comprises a pressing force value estimated by the controller model based on the battery operating data and the sensitivity of battery input and output.

According to some embodiments of the present disclosure, the lookup table is a lookup table associated with the battery operating data and the degree of degradation of the battery assembly.

According to some embodiments of the present disclosure, the pressure regulator comprises a pneumatic actuator or and/a hydraulic actuator.

According to some embodiments of the present disclosure, the characteristic of degradation of the battery assembly may be improved and the lifetime of the battery assembly is increased by controlling the pressure regulator to apply a pressure to the battery assembly.

According to some embodiments of the present disclosure, the use of the battery input/output identification model and the controller model allows a pressure value to be estimated in a case where the degree of degradation of the battery assembly is minimized.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 illustrates a battery management system according to one or more embodiments of the present disclosure;

FIG. 2 illustrates a controller of the battery management system according to one or more embodiments of the present disclosure;

FIG. 3 illustrates a controller of the battery management system according to one or more embodiments of the present disclosure;

FIG. 4 illustrates a controller of the battery management system according to one or more embodiments of the present disclosure;

FIG. 5 illustrates a flowchart showing a method of controlling a battery assembly according to one or more embodiments of the present disclosure;

FIG. 6 is a flowchart illustrating a method of training a battery input/output identification model according to one or more embodiments of the present disclosure;

FIG. 7 illustrates a flowchart showing a method of training a controller model according to one or more embodiments of the present disclosure;

FIG. 8 illustrates an artificial neural network model according to one or more embodiments of the present disclosure;

FIG. 9 illustrates a battery module according to one or more embodiments of the present disclosure;

FIG. 10 illustrates a battery pack according to one or more embodiments of the present disclosure;

FIG. 11 illustrates a vehicle body including a battery pack according to one or more embodiments of the present disclosure and components of the vehicle body.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

A term “battery assembly” used herein may refer to a battery pack, a battery module, or an energy storage system. In addition, the “battery assembly” may refer to a variety of structures including various types of batteries including one or more battery cells.

Secondary batteries may be provided in a variety of products in the form of battery packs or battery modules. The battery pack or battery module is housed in a housing and may be subject to pressure from the housing during repeated charging and discharging. The externally applied compression pressure on the secondary cell may shorten the lifetime of the secondary cell and degrade the secondary cell. To prevent such problems, a method of controlling the compression pressure applied to the secondary cell is desired.

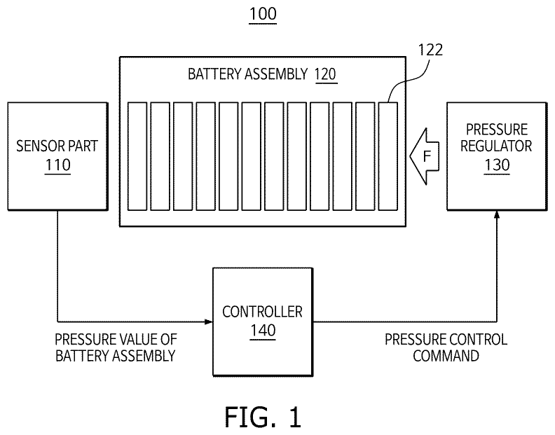

FIG. 1 illustrates a battery management system according to one or more embodiments of the present disclosure.

Referring to FIG. 1, a battery management system 100 according to one or more embodiments may include a sensor part 110, a battery assembly 120, a pressure regulator 130, and a controller 140. The battery management system 100 may correspond to an apparatus for managing the battery assembly 120. In some embodiments, the battery management system 100 may be provided as a part of a battery management system (BMS) of a vehicle.

The battery assembly 120 may include a plurality of battery cells 122. Each of the battery cells 122 may include a rechargeable secondary battery. For example, the battery cells may include nickel cadmium batteries, lead acid batteries, nickel metal hydride (NiMH) batteries, lithium-ion batteries, lithium polymer batteries, all solid state battery, and the like.

The sensor part 110 may measure the pressure of the battery assembly 120. In an example, the sensor part 110 may measure a pressure applied to the battery assembly 120. In another example, the sensor part 110 may measure a pressure applied to each or some of the battery cells 122 of the battery assembly 120. In another example, the sensor part 110 may measure a pressure applied to the battery assembly 120 that occurs during swelling of the battery cells 122. The pressure applied to the battery assembly 120 may increase as the battery cells 122 swell. A pressure value of the battery assembly 120 measured by the sensor part 110 may be transmitted to the controller 140.

The pressure regulator 130 may apply a pressure to the battery assembly 120. For example, the pressure regulator 130 may apply a force to the battery assembly 120 in response to a pressure control command from the controller 140. As a result, the pressure of the battery assembly 120 may be regulated. In an embodiment, the pressure regulator 130 may include a force actuator using hydraulic pressure, pneumatic pressure, and/or electric actuator pressure. However, the present disclosure is not limited thereto.

The sensor part 110, the battery assembly 120, and the pressure regulator 130 are shown as being separated from each other, but this is for illustrative purposes only. For example, in contrast to what is shown, the sensor part 110 and the pressure regulator 130 may be included in the battery assembly 120. In addition, each of the sensor part 110, the battery assembly 120, and the pressure regulator 130 are shown as a single component, but this is for illustrative purposes only. For example, a plurality of sensor parts 110, plurality of battery assemblies 120, and/or plurality of pressure regulators 130 may be disposed in the battery management system 100.

The controller 140 may include a processor and a memory. The controller 140 may receive a pressure value of the battery assembly 120 measured by the sensor part 110. In addition, the controller 140 may receive battery operating data of the battery assembly 120. However, the present disclosure is not limited thereto. For example, at least one processor of the controller 140 may generate the battery operating data of the battery assembly 120 in addition to or alternative to receiving the battery operating data.

The controller 140 may generate the pressure control command based on a pressure value or compressor displacement value of the battery assembly 120. The controller 140 may control the pressure regulator 130 based on the pressure control command. For example, the controller 140 may control the pressure regulator 130 based on the pressure control command so that the pressure regulator 130 has a pressure value or compressor displacement value at which the degree of degradation of the battery assembly is minimized.

The controller 140 is to be interpreted broadly to include a general purpose processor, a central processing unit (CPU), a microprocessor, a digital signal processor (DSP), a controller, a microcontroller, a state machine, and/or the like. In some embodiments, the processor may refer to an application specific integrated circuit (ASIC), a programmable logic device (PLD), a field programmable gate array (FPGA), or the like. The processor may also refer to, for example, a combination of processing devices, such as a combination of a DSP and a microprocessor, a combination of a plurality of microprocessors, a combination of one or more microprocessors coupled with a DSP core, or any other combination of such configurations. The processor may be configured to process instructions from a computer program by performing basic arithmetic, logic, and input/output operations.

The memory is to be interpreted broadly to include any electronic component capable of storing electronic information. The memory may also refer to various types of processor-readable media, such as random access memory (RAM), read only memory (ROM), non-volatile random access memory (NVRAM), programmable read only memory (PROM), erasable programmable read only memory (EPROM), electrically erasable PROM (EEPROM), flash memory, magnetic or optical data storage, registers, and the like. In a case where the processor may read information from the memory and/or write information to the memory, the memory is referred to as being in electronic communication with a processor. The memory integrated into a processor is in electronic communication with the processor.

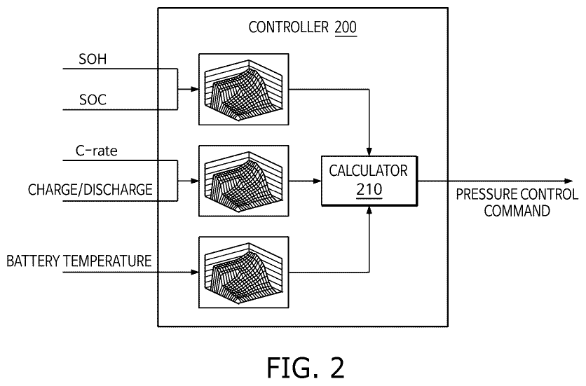

FIG. 2 illustrates a controller of the battery management system according to one or more embodiments of the present disclosure.

Referring to FIG. 2, a controller 200 may generate a pressure control command based on battery operating data. The controller 200 may control the pressure regulator based on a pressure control command.

In some embodiments, the controller 200 may receive the battery operating data. In an example, the battery operating data may include data about at least one of the state of health (SOH), state of charge (SOC), current rate (C-rate), charge/discharge, temperature, and the like of the battery assembly. In another example, the battery operating data may be data associated with the battery cells of the battery assembly (e.g., the SOC, SOH, C-rate, charge/discharge, temperature, and the like of the battery cells).

A calculator 210 of the controller 200 may receive the battery operating data. In some embodiments, a portion of the battery operating data received by the calculator 210 may be processed. The processed battery operating data may be transmitted to the calculator 210. For example, data about the SOH and data about the SOC may be processed considering the relationship therebetween, and data about the C-rate and data about the charge/discharge may be processed considering the relationship therebetween.

The calculator 210 may generate the pressure control command based on the battery operating data. For example, the calculator 210 may calculate the pressure control command by which the degree of degradation of the battery assembly 120 is reduced, based on the battery operating data. The controller 200 may control the pressure regulator based on the pressure control command.

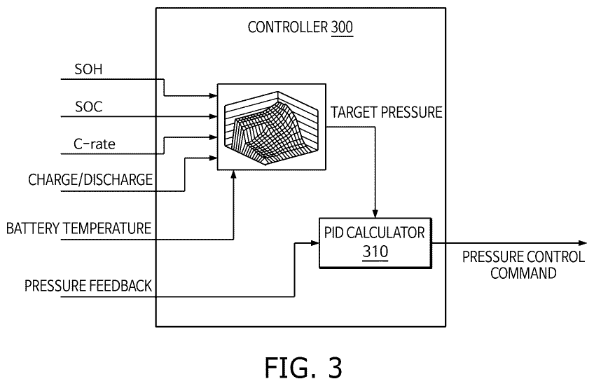

FIG. 3 illustrates a controller of the battery management system according to one or more embodiments of the present disclosure. Compared to FIG. 2, a pressure control command may be generated by additionally considering pressure feedback.

Referring to FIG. 3, the controller 300 may generate the pressure control command based on battery operating data. The controller 300 may control the pressure regulator based on the pressure control command.

In some embodiments, the controller 300 may receive the battery operating data. In an example, the battery operating data may include data about at least one of the SOH, SOC, C-rate, charge/discharge, temperature, pressure feedback, and the like of the battery assembly. In another example, the battery operating data may be data associated with the battery cells of the battery assembly (e.g., the SOC, SOH, C-rate, charge/discharge, temperature, and the like of the battery cells). The controller 300 may calculate a target pressure value based on the SOH, SOC, C-rate, charge/discharge, and temperature data of the battery assembly. The calculated target pressure value may be transmitted to the PID calculator 310.

Subsequently, the PID calculator 310 of the controller 300 may generate the pressure control command based on the target pressure value and the pressure feedback. Herein, the pressure feedback may be a pressure value of the battery assembly measured by the sensor part. The PID calculator 310 may dynamically control the pressure of the battery assembly based on the pressure feedback. For example, the PID calculator 310 may use a proportional integral derivative (PID) control algorithm.

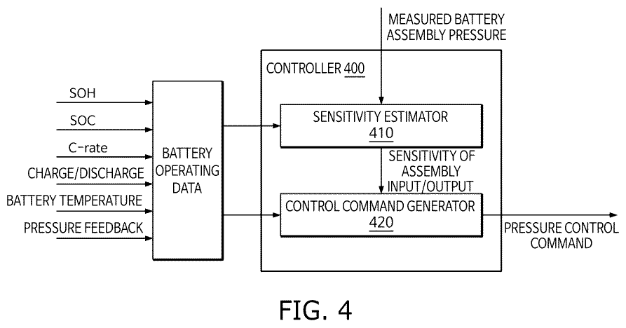

FIG. 4 illustrates a controller of the battery management system according to one or more embodiments of the present disclosure. Compared to FIG. 3, a pressure control command may be generated by additionally considering a measured pressure of the battery assembly and the sensitivity of battery input and output. Accordingly, compared to the controller of the battery management system shown in FIGS. 2 and 3, the pressure control command may be generated in a more sophisticated manner to more accurately control a pressure applied to the battery assembly.

Referring to FIG. 4, a controller 400 according to one or more embodiments may include a sensitivity estimator 410 and a control command generator 420.

The sensitivity estimator 410 may receive battery operating data. Herein, the battery operating data may be data associated with the battery assembly. For example, the battery operating data may include data about at least one of the SOH, SOC, C-rate, charge/discharge, temperature, pressure feedback, and the like of the battery assembly. However, the present disclosure is not limited thereto. For example, the battery operating data may be data associated with respective battery cells or some battery cells of the battery assembly. In a case where the battery operating data is data about a plurality of battery cells, the battery operating data may correspond to data about an average value of data about respective battery cells or data about an average value of values obtained by applying weights to data about respective battery cells.

Although not shown, the controller 400 may generate a portion of the battery operating data. For example, the controller 400 may generate the SOC and SOH data of the battery assembly based on the internal resistance, temperature, output, and the like of the battery assembly.

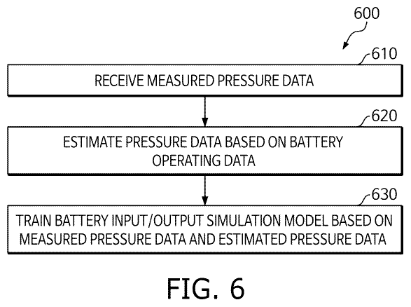

The sensitivity estimator 410 may receive a pressure value of the battery assembly measured by the sensor part. The sensitivity estimator 410 may estimate the sensitivity of battery input and output based on the measured pressure value and the battery operating data. For example, the sensitivity estimator 410 may estimate the sensitivity of battery input and output based on the measured pressure value and the battery operating data. Herein, the sensitivity of battery input and output may be the sensitivity of the battery assembly to a pressure applied to the battery assembly. A battery input/output identification model may be an artificial neural network model trained to identify the input-output sensitivity of the battery assembly. A method of training the battery input/output identification model will be described in detail, for example, with reference to FIG. 6. The sensitivity estimator 410 may transmit the estimated sensitivity of battery input and output to the control command generator 420.

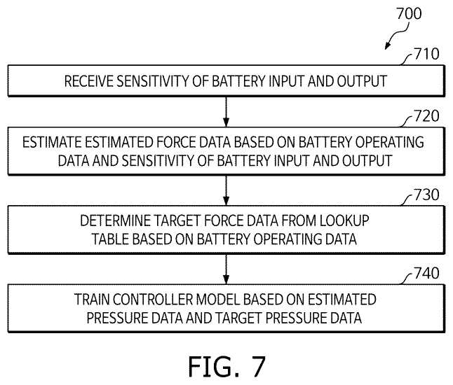

The control command generator 420 may receive the sensitivity of battery input and output transmitted from the sensitivity estimator 410. In addition, the control command generator 420 may receive the battery operating data. The control command generator 420 may generate the pressure control command based on the sensitivity of battery input and output and the battery operating data. For example, the control command generator 420 may generate the pressure control command based on the sensitivity of battery input and output and the battery operating data using the controller model. The controller model may be an artificial neural network model trained to minimize the degree of degradation of the battery assembly. The method of training the controller model will be described in detail, for example, with reference to FIG. 7. The controller 400 may control the pressure regulator based on the pressure control command generated by the control command generator 420.

In some embodiments, the controller 400 may generate the pressure control command using a model reference adaptive control (MRAC) algorithm. For example, the controller 400 may use the battery input/output identification model as an identifier and the controller model as a controller.

In FIG. 4, respective components (e.g., the sensitivity estimator 410 and the control command generator 420) of the controller 400 may represent functionally distinct functional elements, and may be implemented in a manner such that the components are integrated with each other in an actual physical environment. In another example, the respective components of the controller 400 may be implemented separately in an actual physical environment.

The controllers according to various embodiments are illustrated in FIGS. 2 to 4, respectively, but some functions or operations of the respective controllers may be merged with each other. For example, the operation of the controller shown in FIG. 2 may be realized by the controller shown in FIG. 2 or 3. Data about the SOH and data about the SOC may be processed in consideration of the relationship therebetween, and the operation of the controller to process data about the C-rate and data about the charge/discharge in consideration of the relationship therebetween may be realized by the controller shown in FIG. 3 or 4.

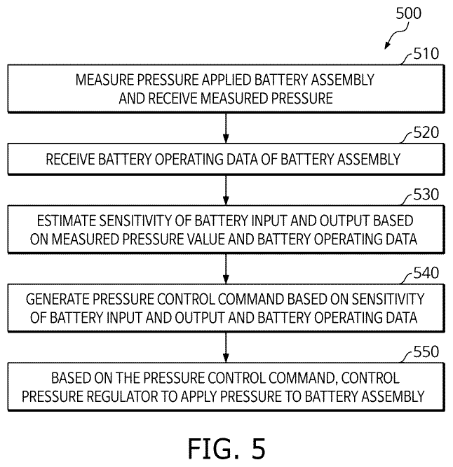

FIG. 5 illustrates a flowchart showing a method of controlling a battery assembly according to one or more embodiments of the present disclosure. At least one step of a method 500 of controlling a battery assembly may be executed by the controller.

Referring to FIG. 5, the method 500 of controlling a battery assembly may include a step 510 of measuring a pressure applied to the battery assembly and receiving the measured pressure by the controller. For example, the sensor part may measure the pressure applied to the battery assembly to obtain the measured pressure value and transmit the measured pressure value to the controller. The controller may receive the measured pressure value measured by the sensor part.

Thereafter, the controller may receive battery operating data of the battery assembly in 520. However, the present disclosure is not limited thereto. In an example, the controller may receive the battery operating data before receiving the measured pressure value. In another example, the controller may receive the battery operating data and the measured pressure value at a substantially same time. In some embodiments, the battery operating data may include at least one of SOH, SOC, C-rate, charge/discharge, temperature, voltage, internal resistance, or pressure associated with the battery assembly. In another example, the battery operating data may be data associated with the battery cells of the battery assembly.

Subsequently, the controller may estimate the sensitivity of battery input and output based on the measured pressure value and the battery operating data in 530. For example, the controller may estimate the sensitivity of battery input and output using the battery input/output identification model. The battery input/output identification model may estimate a pressure associated with the swelling of the battery and estimate the pressure of the battery assembly, based on the battery operating condition. The battery input/output identification model may be model trained to identify the input-output sensitivity of the battery assembly.

The sensitivity of battery input and output may represent the sensitivity of the battery assembly to a pressure applied to the battery assembly. In some embodiments, the sensitivity of battery input and output may be defined by the following equation.

$$Sensitivity of battery input and output = \partial y / \partial u$$

Herein, y may be a pressure output of the battery assembly, and u may be a force or compressor displacement value input applied to the battery assembly.

Thereafter, the controller may generate a pressure control command based on the sensitivity of battery input and output and the battery operating data in 540. For example, the controller may generate the pressure control command using the controller model. The controller model may be a model trained to determine a pressing force value by which the degree of degradation of the battery assembly is minimized.

Subsequently, based on the pressure control command, the controller may control the pressure regulator to apply a pressure to the battery assembly in 550. As a result, the pressure of the battery assembly may be dynamically regulated, and the degree of degradation of the battery assembly may be improved.

In some embodiments, after the controller controls the pressure regulator, the controller may measure a pressure applied to the battery assembly to obtain a changed pressure value. For example, after the controller controls the pressure regulator, a measuring part may measure a changed pressure applied to the battery assembly. The controller may receive a pressure value measured by the measuring part.

FIG. 6 is a flowchart illustrating a method of training a battery input/output identification model according to one or more embodiments of the present disclosure. A method 600 of training a battery input/output identification model may be executed by at least one processor of the controller.

Referring to FIG. 6, the method 600 of training a battery input/output identification model may begin with the processor receiving measured pressure data in 610. Herein, the measured pressure data may include a pressure value of the battery assembly measured by the sensor part.

Thereafter, the processor may estimate pressure data of the battery assembly based on battery operating data in 620. Herein, the estimated pressure data may include a pressure value of the battery assembly estimated by the battery input/output identification model, based on the battery operating data.

Subsequently, the processor may train the battery input/output identification model based on a pair of the measured pressure data and the estimated pressure data. For example, the processor may train the battery input/output identification model so that an error in a pair of the measured pressure data and the estimated pressure data is reduced. In some embodiments, the method of training a battery input/output identification model may be implemented using a gradient descent method. However, the present disclosure is not limited thereto. The trained battery input/output identification model may more accurately identify the input-output sensitivity of the battery assembly.

FIG. 7 illustrates a flowchart showing a method of training a controller model according to one or more embodiments of the present disclosure. A method 700 of training a controller model may be executed by at least one processor of the controller.

Referring to FIG. 7, the method 700 of training a controller model may begin with receiving the sensitivity of battery input and output in 710. For example, the processor may receive the sensitivity of battery input and output generated by the battery input/output identification model.

Thereafter, the processor may estimate estimated force data based on the battery operating data and the sensitivity of battery input and output in 720. Herein, the estimated force data may include a pressing force value estimated by the controller model based on the battery operating data and the sensitivity of battery input and output.

Subsequently, the processor may determine target force data from a lookup table, based on the battery operating data in 730. Herein, the target force data may include the determined pressing force value from the predetermined lookup table. The lookup table may be a predetermined lookup table associated with the battery operating data and the degree of degradation of the battery assembly. For example, the lookup table may represent the degree of degradation of the battery assembly according to the battery operating data. In some embodiments, the lookup table may be stored in the memory of the controller.

Thereafter, the processor may train the controller model based on the estimated force data and the target force data. For example, the processor may train the controller model so that an error of a pair of the estimated force data and the target force data is reduced. In some embodiments, the method of training a controller model may be implemented using a gradient descent method. However, the present disclosure is not limited thereto. The trained controller model may more accurately estimate the pressure value at which the degree of degradation of the battery assembly is minimized.

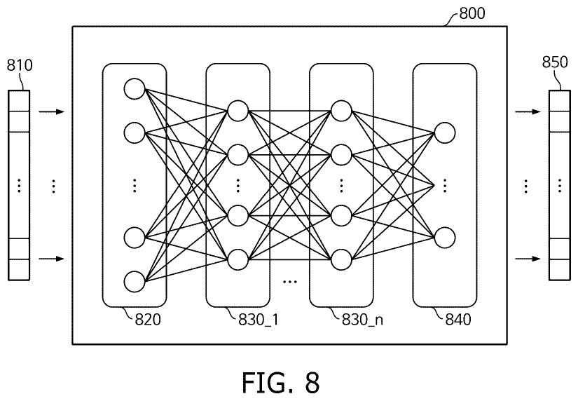

FIG. 8 illustrates an artificial neural network model according to one or more embodiments of the present disclosure. An artificial neural network model 800 is an example of a machine learning model, and is a statistical learning algorithm implemented based on the structure of a biological neural network or a structure for implementing the same algorithm in machine learning technology and cognitive science.

According to one or more embodiments, the artificial neural network model 800 may represent a machine learning model having a problem solving capability, wherein the machine learning model is trained to reduce an error between a correct output and an estimated output in response to a specific input by repeatedly adjusting the weights of synapses by nodes, i.e., artificial neurons, of a network formed by connecting the synapses as in a biological neural network. For example, the artificial neural network model 800 may include any probability model, a neural network model, and the like used in artificial intelligence learning methods such as machine learning and deep learning.

According to one or more embodiments, the method of controlling a battery assembly described above may include the form of at least one artificial neural network model 800. For example, the battery input/output identification model and the controller model may be generated in the form of the artificial neural network model 800. The battery input/output identification model may identify the input-output sensitivity of the battery assembly using the artificial neural network model 800. The controller model may calculate a pressure value at which the degree of degradation of the battery assembly is minimized using the artificial neural network model 800.

The artificial neural network model 800 is implemented as a multilayer perceptron (MLP) including multilayer nodes and connections of the nodes. The artificial neural network model 800 according to the present embodiment may be implemented using one of a variety of artificial neural network model structures including the MLP. As shown in FIG. 8, the artificial neural network model 800 includes an input layer configured to receive an input signal or data 810 from an external source, an output layer configured to output an output signal or data 850 in response to the input data, and n number of hidden layers 830_1 to 830_n positioned between the input layer 810 and the output layer 820 to receive a signal from the input layer, extract a characteristic from the signal, and deliver the same to the output layer (where n is a positive integer). Herein, the output layer receives a signal from the hidden layers 830_1 to 830_n and outputs the signal to the outside.

The method of training the artificial neural network model 800 includes a supervised learning method in which learning is performed to be optimized to solve a problem in response to input of a teacher signal (i.e., answer) and an unsupervised learning method in which no teacher signal is required. According to one or more embodiments, the battery management system may directly generate learning data for training the artificial neural network model 800. For example, the battery management system may monitor the battery assembly and generate battery operating data (e.g., SOH, SOC) based on the measured data (e.g., temperature, internal resistance, or pressure).

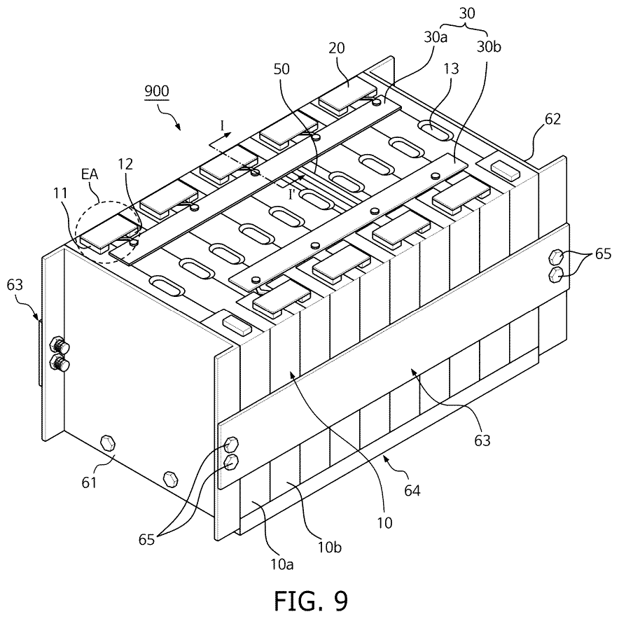

FIG. 9 illustrates a battery module according to one or more embodiments of the present disclosure. The battery assembly described above with reference to FIGS. 1 to 5 may include a battery module 900 shown in FIG. 9.

Referring to FIG. 9, the battery module 900 according to one or more embodiments of the present disclosure includes electrode units 11 and 12, a plurality of battery cells 10 arranged in one direction, a connection tab 20 connecting a battery cell 10a to an adjacent battery cell 10b, and a protection circuit module 30 having one end connected to the connection tab 20. The protection circuit module 30 may include a battery management system (BMS). Further, the connection tab 20 may include a body portion in contact with the electrode units 11 and 12 between the adjacent battery cells 10a and 10b and an extension portion extending from the body portion and connected to the protection circuit module 30. The connection tab 20 may be, for example, a bus bar.

Each battery cell 10 may include a battery case, an electrode assembly received (or accommodated) in the battery case, and an electrolyte. The electrode assembly and the electrolyte react electrochemically to store and release (e.g., generate) energy. Terminal parts 11 and 12 electrically connected to the connection tab 20 and a vent 13 as a discharge passage for gas generated inside the battery case may be provided on one side of (e.g., an upper side of) the battery cell 10. The terminal parts 11 and 12 of the battery cell 10 may be a positive electrode terminal 11 and a negative electrode terminal 122 having different polarities from each other, and the terminal parts 11 and 12 of the adjacent battery cells 10a and 10b may be electrically connected to each other in series or parallel by the connection tab 20, to be described in more detail below. Although a serial connection has been described as an example, the connection structure is not limited thereto, and various connection structures may be employed as desired or necessary. In addition, the number and arrangement of battery cells is not limited to the structure shown in FIG. 9 and may be changed as desired or necessary.

The battery cells 10 may be arranged in (e.g., may be stacked in) one direction so that the wide surfaces of the battery cells 10 face each other, and the battery cells 10 may be fixed by the housings 61, 62, 63, and 64. The housings 61, 62, 63, and 64 may include a pair of end plates 61 and 62 facing the wide surfaces of the battery cell 10 and a side plate 63 and a bottom plate 64 connecting the pair of end plates 61 and 62 to each other. The side plate 63 may support side surfaces of the battery cells 10, and the bottom plate 64 may support bottom surfaces of the battery cells 10. In addition, the pair of end plates 61 and 62, the side plate 63 and the bottom plate 64 may be connected by bolts 65 and/or any other suitable fastening members and methods known to those of ordinary skill in the art.

The protection circuit module 30 may have electronic components and protection circuits mounted thereon and may be electrically connected to connection tabs 20, to be described in more detail later. The protection circuit module 30 includes a first protection circuit module 30a and a second protection circuit module 30b extending along the direction in which the battery cells 100 are arranged in different locations. The first protection circuit module 30a and the second protection circuit module 30b may be spaced from each other at a suitable interval (e.g., a predetermined interval) and arranged parallel to each other to be electrically connected to adjacent connection tabs 20, respectively. For example, the first protection circuit module 30a extends on one side of the upper portion of the battery cells 10 along the direction in which the battery cells 10 are arranged, and the second protection circuit module 30b extends to the other upper side of the battery cells 10 along the direction in which the battery cells 10 are arranged. The second protection circuit module 30b may be spaced from the first protection circuit module 30a at a suitable interval (e.g., a predetermined interval) with the vents 34 interposed therebetween but may be disposed parallel to the first protection circuit module 30a. As such, the two protection circuit modules are spaced from each other side-by-side along the direction in which the battery cells 10 are arranged, thereby reducing or minimizing the area of the printed circuit board (PCB) constituting the protection circuit module. By separately configuring the protection circuit module into two protection circuit modules, unnecessary PCM area can be reduced or minimized. In addition, the first protection circuit module 30a and the second protection circuit module 30b may be connected to each other by a conductive connection member 50. One side of the conductive connection member 50 is connected to the first protection circuit module 30a, and the other side thereof is connected to the second protection circuit module 30b so that the two protection circuit modules 30a and 30b can be electrically connected with each other.

The connection may be performed by any one of soldering, resistance welding, laser welding, projection welding and/or any other suitable connection methods known to those of ordinary skill in the art.

In addition, the connection member 50 may be, for example, an electric wire. In addition, the connection member 50 may be made of a material having elasticity or flexibility. By the connecting member 50, it may be possible to check and manage whether the voltage, temperature, and/or current of the battery cells 10 are normal. For example, the information received by the first protection circuit module from connection tabs adjacent to the first protection circuit module, such as voltage, current, and/or temperature, and the information received from connection tabs adjacent to the second protection circuit module, such as voltage, current, and/or temperature, may be integrated and managed by the protection circuit module through the connection member 50.

In addition, when the battery cell 10 swells, shocks may be absorbed by the elasticity or flexibility of the connection member 50, thereby preventing the first and second protection circuit modules 30a and 30b from being damaged.

In addition, the shape and structure of the connection member 50 is not limited to the shape and structure shown in FIG. 8.

As described above, because the protection circuit module 30 is provided as the first and second protection circuit modules 30a and 30b, the area of the PCB constituting the protection circuit module can be reduced or minimized, and the space inside the battery module can be secured, which improves work efficiency by facilitating a fastening work for connecting the connection tab 20 and the protection circuit module 30 and repair work if (or when) an abnormality is detected in the battery module.

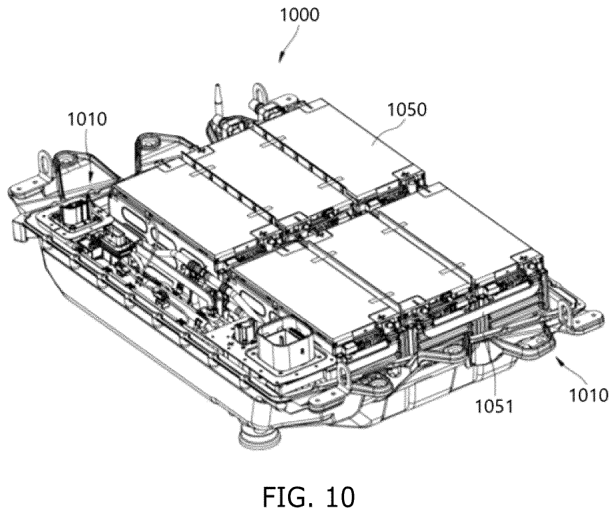

FIG. 10 illustrates a battery pack according to one or more embodiments of the present disclosure. The battery assembly described above with reference to FIGS. 1 to 5 may include a battery pack 1000 shown in FIG. 10.

Referring to FIG. 10, The battery pack 1000 may include a plurality of battery modules 1050 and a housing 1010 for accommodating the battery modules 1050. For example, the housing 1010 may include first and second housings and coupled in opposite directions through the battery modules 1050. The battery modules 1050 may be electrically connected to each other by using a bus bar 1051, and the battery modules 1050 may be electrically connected to each other in a series/parallel or series-parallel mixed method, thereby obtaining desired (e.g., required) electrical output.

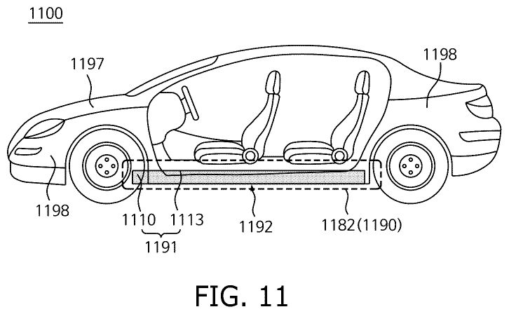

FIG. 11 illustrates a vehicle body including a battery pack according to one or more embodiments of the present disclosure and components of the vehicle body. The battery assembly described above with reference to FIGS. 1 to 7 may include a battery pack 1191 shown in FIG. 11.

Referring to FIG. 11, a battery pack 1191 may include a battery pack cover 1113, which is a part of a vehicle underbody 1192, and a pack frame 11110 disposed under the vehicle underbody 1192. The pack frame 1110 and the battery pack cover 1113 may be integrally formed with a vehicle floor 1182.

The vehicle underbody 92 separates the inside and outside of a vehicle, and the pack frame 10 may be disposed outside the vehicle. A vehicle 1100 may be formed by combining additional parts, such as a hood 1197 in front of the vehicle and fenders 1198 respectively located in the front and rear of the vehicle to a vehicle body.

The vehicle 1100 may further include a vehicle floor 1182, which is one of the vehicle body parts 1190 including the battery pack 1191 including the pack frame 1110 and the battery pack cover 1113.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. A method of controlling a battery assembly, the method comprising:
measuring a pressure applied to a battery assembly to obtain a measured pressure value;
receiving battery operating data of the battery assembly;
estimating a sensitivity of battery input and output based on the measured pressure value and the battery operating data; and
generating a pressure control command based on the sensitivity of battery input and output and the battery operating data,
wherein the sensitivity of battery input and output represents a sensitivity of the battery assembly to the pressure applied to the battery assembly.

2. The method as claimed in claim 1, wherein the battery operating data comprises data about at least one of a state of health (SOH), a state of charge (SOC), a current rate (C-rate), charge/discharge, a temperature, a voltage, an internal resistance, or a pressure associated with the battery assembly.

3. The method as claimed in claim 1, wherein the estimating of the sensitivity of battery input and output comprises estimating the sensitivity of battery input and output using a battery input/output identification model,
wherein the battery input/output identification model is a model trained to identify the input-output sensitivity of the battery assembly.

4. The method as claimed in claim 3, wherein the battery input/output identification model is trained based on measured pressure data and estimated pressure data,
wherein the measured pressure data comprises the measured pressure value obtained by measuring the pressure applied to the battery assembly, and
the estimated pressure data comprises a pressure value estimated by the battery input/output identification model based on the battery operating data.

5. The method as claimed in claim 3, wherein the battery input/output identification model is a model trained using a gradient descent method.

6. The method as claimed in claim 1, wherein the generating of the pressure control command comprises generating the pressure control command using a controller model,
wherein the controller model is a model trained to determine a pressing force value at which a degree of degradation of the battery assembly is minimized.

7. The method as claimed in claim 6, wherein the controller model is trained based on target force data and estimated force data,
wherein the target force data comprises a pressing force value determined from a predetermined lookup table, and
the estimated force data comprises a pressing force value estimated by the controller model based on the battery operating data and the sensitivity of battery input and output.

8. The method as claimed in claim 7, wherein the lookup table is a lookup table associated with the battery operating data and the degree of degradation of the battery assembly.

9. The method as claimed in claim 6, wherein the controller model is a model trained using a gradient descent method.

10. The method as claimed in claim 1, wherein the sensitivity of battery input and output is defined by the following equation:
the sensitivity of battery input and output=∂y/∂u,
where y is a pressure output of the battery assembly, and u is a force input applied to the battery assembly.

11. The method as claimed in claim 1, further comprising controlling a pressure regulator to apply a pressure to the battery assembly, based on the pressure control command.

12. The method as claimed in claim 11, further comprising, after the controlling of the pressure regulator, measuring a pressure applied to the battery assembly to obtain a changed pressure value.

13. A battery management system comprising:
a battery assembly comprising a plurality of battery cells;
a sensor part configured to measure a pressure applied to the battery assembly;
a pressure regulator provided on the battery assembly; and
a controller configured to receive a measured pressure value from the sensor part and control the pressure regulator,
wherein the controller comprises:
a sensitivity estimator configured to estimate a sensitivity of battery input and output based on the measured pressure value and battery operating data; and
a control command generator configured to generate a pressure control command based on the sensitivity of battery input and output and the battery operating data.

14. The battery management system as claimed in claim 13, wherein the battery operating data comprises data about at least one of a state of health (SOH), a state of charge (SOC), a current rate (C-rate), charge/discharge, a temperature, a voltage, an internal resistance, or a pressure associated with the battery assembly.

15. The battery management system as claimed in claim 13, wherein the sensitivity estimator estimates the sensitivity of battery input and output using a battery input/output identification model,
wherein the battery input/output identification model is trained to identify the input-output sensitivity of the battery assembly.

16. The battery management system as claimed in claim 15, wherein the battery input/output identification model is trained based on measured pressure data and estimated pressure data,
wherein the measured pressure data comprises the measured pressure value obtained by measuring the pressure applied to the battery assembly, and
the estimated pressure data comprises a pressure value estimated by the battery input/output identification model based on the battery operating data.

17. The battery management system as claimed in claim 13, wherein the control command generator generates the pressure control command using a controller model,
wherein the controller model is a model trained to minimize a degree of degradation of the battery assembly.

18. The battery management system as claimed in claim 17, wherein the controller model is trained based on target force data and estimated force data,
wherein the target force data comprises a pressing force value determined from a predetermined lookup table, and
the estimated force data comprises a pressing force value estimated by the controller model based on the battery operating data and the sensitivity of battery input and output.

19. The battery management system as claimed in claim 18, wherein the lookup table is a lookup table associated with the battery operating data and the degree of degradation of the battery assembly.

20. The battery management system as claimed in claim 13, wherein the pressure regulator comprises a pneumatic actuator and/or a hydraulic actuator.
